(19) United States
(12) Patent Application Publication
(10) Pub. No.: US 2025/0113530 A1
(43) Pub. Date: Apr. 3, 2025

(54) VERTICAL TRANSISTOR, LIGHT DETECTION APPARATUS, AND ELECTRONIC DEVICE

(71) Applicant: SONY SEMICONDUCTOR SOLUTIONS CORPORATION, KANAGAWA (JP)

(72) Inventors: KENSHI NAGASATO, KANAGAWA (JP); KENTARO EDA, KANAGAWA (JP)

(21) Appl. No.: 18/832,792

(22) PCT Filed: Jan. 17, 2023
(86) PCT No.: PCT/JP2023/001099

§ 371 Date: Jul. 24, 2024

(30) Foreign Application Priority Data
Feb. 2, 2022 (JP) 2022-015139

(51) Int. Cl. H10D 30/63; H10D 64/27; H10F 39/12

(52) U.S. Cl. CPC H10D 30/63; H10D 64/513; H10F 39/12

(57) ABSTRACT

The present disclosure relates to a vertical transistor, a light detection apparatus, and an electronic device that can improve transistor characteristics in the vertical transistor. The vertical transistor includes a vertical gate electrode including: a first gate electrode layer formed on a side wall and a bottom portion of a trench and having a first impurity concentration; and a second gate electrode layer formed on the first gate electrode layer and having a second impurity concentration different from the first impurity concentration. The present disclosure can be applied to, for example, a transfer transistor or the like arranged in each pixel of the pixel array section.

### TECHNICAL FIELD

The present disclosure relates to a vertical transistor, a light detection apparatus, and an electronic device, and particularly relates to a vertical transistor, a light detection apparatus, and an electronic device capable of improving transistor characteristics.

### BACKGROUND ART

A vertical transistor having a gate electrode structure in which a part of a gate electrode is embedded in a semiconductor substrate is known. As a method of forming the gate electrode of the vertical transistor, for example, there is a method of forming a trench in a semiconductor substrate and ion-implanting an N-type impurity such as phosphorus (P) into an electrode material (for example, polysilicon) formed inside the trench and on the upper surface of the substrate (see, for example, Patent Document 1). In addition, as another method, for example, there is a method of forming a film of polysilicon doped with phosphorus (P) by a chemical vapor deposition (CVD) method, such as a phosphorus doped amorphous silicon (PDAS) film or a phosphorus doped polysilicon (DOPOS) film.

### CITATION LIST

### Patent Document

Patent Document 1: WO 2021/149380 A

### SUMMARY OF THE INVENTION

### Problems to be Solved by the Invention

However, in the method of forming by ion implantation, the depth to which ions are implanted in the planar portion of the upper surface of the substrate and the trench portion is different, so that it is difficult to achieve both the planar portion and the trench portion. That is, there is a concern that ions penetrate into the substrate in the planar portion, or on the contrary, ions cannot be sufficiently implanted in the trench portion, and the conductor becomes nonconductive in the deep portion of the trench. In the method of forming a film of polysilicon doped with phosphorus, since the film is formed on the entire surface of the semiconductor substrate, only an N-type MOS transistor can be formed in the same plane.

The present disclosure has been made in view of such a situation, and an object thereof is to improve transistor characteristics in a vertical transistor.

### Solutions to Problems

A vertical transistor according to a first aspect of the present disclosure includes a vertical gate electrode including: a first gate electrode layer formed on a side wall and a bottom portion of a trench and having a first impurity concentration; and a second gate electrode layer formed on the first gate electrode layer and having a second impurity concentration different from the first impurity concentration.

A light detection apparatus according to a second aspect of the present disclosure includes a vertical transistor including a vertical gate electrode including: a first gate electrode layer formed on a side wall and a bottom portion of a trench and having a first impurity concentration; and a second gate electrode layer formed on the first gate electrode layer and having a second impurity concentration different from the first impurity concentration.

An electronic device according to a third aspect of the present disclosure includes a light detection apparatus including a vertical transistor including a vertical gate electrode including: a first gate electrode layer formed on a side wall and a bottom portion of a trench and having a first impurity concentration; and a second gate electrode layer formed on the first gate electrode layer and having a second impurity concentration different from the first impurity concentration.

In the first to third aspects of the present disclosure, in the vertical transistor, there is provided a vertical gate electrode including: a first gate electrode layer formed on a side wall and a bottom portion of a trench and having a first impurity concentration, and a second gate electrode layer formed on the first gate electrode layer and having a second impurity concentration different from the first impurity concentration.

The light detection apparatus and the electronic device may be independent apparatuses or may be modules incorporated in another apparatus.

### BRIEF DESCRIPTION OF DRAWINGS

FIG. 1 is a diagram illustrating a schematic configuration of an example of a light detection apparatus as an embodiment of the present disclosure.

FIG. 2 is a cross-sectional view of one pixel in a pixel array section.

FIG. 3 is a diagram for explaining a method of manufacturing a vertical gate electrode of a transfer transistor.

FIG. 4 is a diagram for explaining a method of manufacturing a vertical gate electrode of a transfer transistor.

FIG. 5 is a diagram for explaining a method of manufacturing a vertical gate electrode of a transfer transistor.

FIG. 6 is a diagram for explaining an effect of a vertical gate electrode of the present disclosure.

FIG. 7 is a diagram for explaining an effect of a vertical gate electrode of the present disclosure.

FIG. 8 is a block diagram illustrating a configuration example of an electronic device to which the technology of the present disclosure is applied.

FIG. 9 is a diagram illustrating a use example in a case where the light detection apparatus of the present disclosure is an image sensor.

FIG. 10 is a view depicting an example of a schematic configuration of an endoscopic surgery system.

FIG. 11 is a block diagram depicting an example of a functional configuration of a camera head and a camera control unit (CCU).

FIG. 12 is a block diagram depicting an example of schematic configuration of a vehicle control system.

FIG. 13 is a diagram of assistance in explaining an example of installation positions of an outside-vehicle information detecting section and an imaging section.

### MODE FOR CARRYING OUT THE INVENTION

Hereinafter, a mode for carrying out the technology of the present disclosure (hereinafter, referred to as an embodiment) will be described with reference to the accompanying drawings. The description is given in the following order.
1. Schematic Configuration Example of Light Detection Apparatus
2. Cross-Sectional View of Pixel
3. Method of Manufacturing Vertical Gate Electrode
4. Effect of Vertical Gate Electrode of Present Disclosure
5. Configuration Example of Electronic Device
6. Use Example of Image Sensor
7. Application Example to Endoscopic Surgery System
8. Application Example to Mobile Body

Note that, in the drawings referred to in the following description, the same or similar parts are denoted by the same or similar reference signs, and redundant description will be omitted as appropriate. The drawings are schematic, and the relationship between the thickness and the plane dimension, the ratio of the thickness of each layer, and the like are different from the actual ones. Furthermore, the drawings may include portions having different dimensional relationships and ratios.

Furthermore, definition of directions such as upward and downward directions, and the like in the following description is merely the definition for convenience of description, and does not limit the technical idea of the present disclosure. For example, when an object is observed by rotating the object by 90°, the up and down are converted into and read as left and right, and when the object is observed by rotating the object by 180°, the up and down are inverted and read.

### <1. Schematic Configuration Example of Light Detection Apparatus>

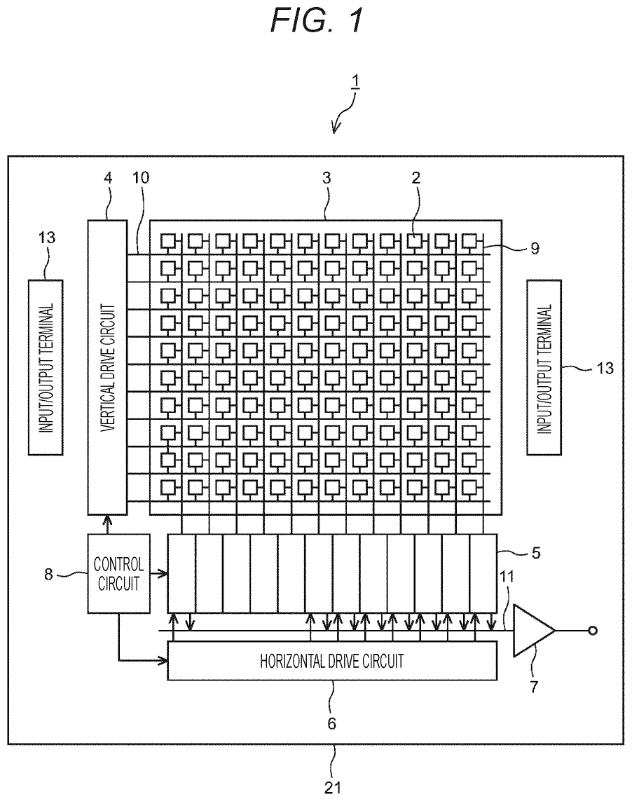

FIG. 1 is a diagram illustrating a schematic configuration of a light detection apparatus as an embodiment of the present disclosure.

The light detection apparatus 1 of FIG. 1 includes a pixel array section 3 in which pixels 2 are arranged in a two-dimensional array on a semiconductor substrate 21 using, for example, silicon (Si) as a semiconductor, and a peripheral circuit section around the pixel array section 3. The peripheral circuit section includes a vertical drive circuit 4, a column signal processing circuit 5, a horizontal drive circuit 6, an output circuit 7, a control circuit 8, and the like.

The pixel 2 includes a photodiode as a photoelectric conversion section and a plurality of pixel transistors. The plurality of pixel transistors includes, for example, four of a transfer transistor, a selection transistor, a reset transistor, and an amplification transistor, and each includes a MOS transistor (MOS FET).

The pixels 2 may have a shared pixel structure. This shared pixel structure includes a plurality of photodiodes, a plurality of transfer transistors, one shared floating diffusion, and one shared another pixel transistor. That is, in the shared pixel structure, photodiodes and transfer transistors that constitute a plurality of unit pixels are configured to share another each one of pixel transistors.

The control circuit 8 receives an input clock and data instructing an operation mode or the like, and outputs data such as internal information of the light detection apparatus 1. That is, the control circuit 8 generates a clock signal and a control signal which serve as a reference for operation of the vertical drive circuit 4, the column signal processing circuit 5, the horizontal drive circuit 6, and the like on the basis of a vertical synchronization signal, a horizontal synchronization signal, and a master clock. Then, the control circuit 8 outputs the generated clock signal and control signal to the vertical drive circuit 4, the column signal processing circuit 5, the horizontal drive circuit 6, and the like.

The vertical drive circuit 4 including a shift register, for example, selects a predetermined pixel drive line 10 and supplies a pulse for driving the pixel 2 to the selected pixel drive line 10 to drive the pixels 2 row by row. That is, the vertical drive circuit 4 selectively scans each pixel 2 of the pixel array section 3 sequentially in the vertical direction in units of rows, and supplies a signal based on a signal charge generated according to the amount of received light in the photoelectric conversion section of each pixel 2 to the column signal processing circuit 5 through a vertical signal line 9.

The column signal processing circuit 5 arranged for each column of the pixels 2 performs signal processing such as noise removal on the signals output from the pixels 2 of one column for each pixel column. For example, the column signal processing circuit 5 performs signal processing such as correlated double sampling (CDS) for removing a fixed pattern noise specific to the pixel and AD conversion.

The horizontal drive circuit 6 including a shift register, for example, sequentially selects each of the column signal processing circuits 5 by sequentially outputting horizontal scanning pulses and outputs the pixel signal from each of the column signal processing circuits 5 to a horizontal signal line 11.

The output circuit 7 performs signal processing on the signals sequentially supplied from each of the column signal processing circuits 5 through the horizontal signal line 11 and outputs the processed signals. In the output circuit 7, for example, there is a case where only buffering is performed, or a case where black level adjustment, column variation correction, various types of digital signal processing, and the like are performed. An input/output terminal 13 communicates signals with the outside.

The light detection apparatus 1 configured as described above generates a signal corresponding to the amount of received light of each pixel 2 of the pixel array section 3 and outputs the signal to the outside. The light detection apparatus 1 can be, for example, a solid-state imaging apparatus that detects a distribution of the amount of incident light of infrared light or visible light and captures the distribution as an image, or a light receiving apparatus of a distance measuring system that receives infrared light and measures a distance to a subject by a direct ToF method or an indirect ToF method.

### <2. Cross-Sectional View of Pixel>

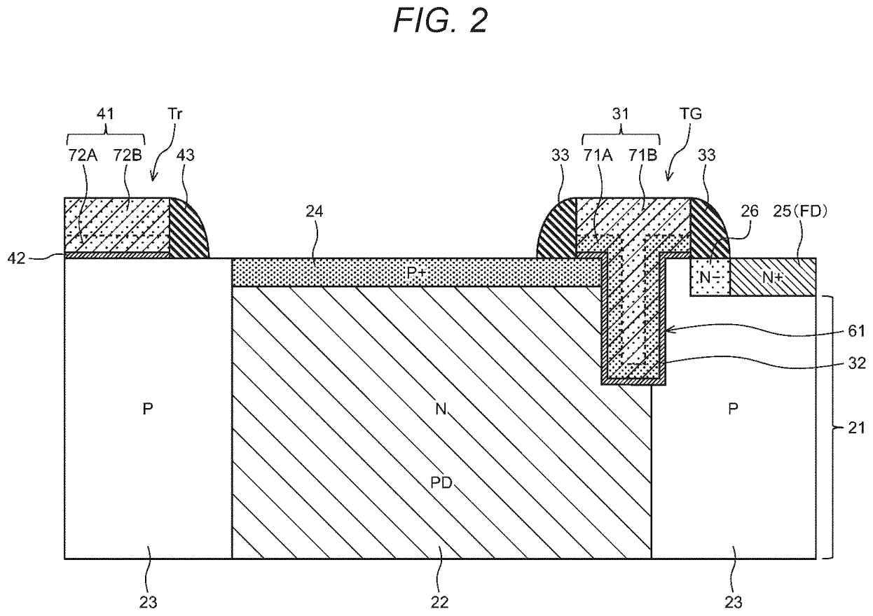

FIG. 2 is a cross-sectional view of one pixel in the pixel array section 3 of the light detection apparatus 1.

Each pixel 2 includes at least a photodiode PD and a transfer transistor TG.

The photodiode PD is a photoelectric conversion section that photoelectrically converts incident light, and includes an N-type semiconductor region 22 formed on a semiconductor substrate 21 as an N-type that is the first conductivity type. In FIG. 2, an upper side surface of the semiconductor substrate 21 is a front surface of the semiconductor substrate 21, a lower side surface of the semiconductor substrate 21 is a back surface of the semiconductor substrate 21, and is a light incident surface. Therefore, the photodiode PD photoelectrically converts light incident from the back surface of the semiconductor substrate 21 and generates electrons which are signal charges.

A P-well 23 which is a P-type well region of a second conductivity type opposite to the first conductivity type is formed around the photodiode PD which is a boundary portion with the adjacent pixel. The P-well 23 separates the photodiode PD formed in each pixel 2. A P-type semiconductor region 24, which is a pinning layer for suppressing generation of dark current, is formed in the vicinity of the interface on the front surface side of the semiconductor substrate 21, which is an upper layer of the N-type semiconductor region 22 as the photodiode PD. The “P+” of the P-type semiconductor region 24 illustrated in FIG. 2 indicates that the P-type impurity concentration is higher than that of the P-well 23.

The transfer transistor TG includes an N-type MOS transistor (MOS FET), and includes a vertical gate electrode 31, a gate insulating film 32, and a sidewall 33. The transfer transistor TG is a vertical transistor having a vertical gate electrode 31 in which a part of a gate electrode is embedded in the semiconductor substrate 21.

The vertical gate electrode 31 includes a lower first gate electrode layer 71A and an upper second gate electrode layer 71B. The lower first gate electrode layer 71A is formed on the side wall and the bottom portion of the trench 61 dug in the depth direction of the semiconductor substrate 21, and the upper second gate electrode layer 71B is formed inside the first gate electrode layer 71A in the trench 61 and on the first gate electrode layer 71A on the semiconductor substrate 21. The impurity concentrations of the first gate electrode layer 71A and the second gate electrode layer 71B are different, and specifically, the impurity concentration of the upper second gate electrode layer 71B is lower than that of the lower first gate electrode layer 71A.

The transfer transistor TG transfers a charge (electron) generated by the photodiode PD to a floating diffusion (FD). The FD is formed by a high-concentration N-type semiconductor region (N-type diffusion layer) 25 on the side opposite to the region where the photodiode PD is formed with reference to the vertical gate electrode 31. In a region under the sidewall 33 adjacent to the high-concentration N-type semiconductor region 25, an N-type semiconductor region 26, which is a lightly doped drain (LDD) region formed with an impurity concentration lower than that of the high-concentration N-type semiconductor region 25, is formed. The “N-” of the N-type semiconductor region 26 in FIG. 2 indicates that the impurity concentration is lower than that of the high-concentration N-type semiconductor region 25 represented by “N+”.

A planar transistor Tr, which is a MOS transistor (MOS FET) of the same conductivity type (N type) as the transfer transistor TG, is formed at a predetermined position on the semiconductor substrate 21 at the pixel boundary portion where the P-well 23 is formed. The planar transistor Tr is any of an amplification transistor, a reset transistor, and a selection transistor, and may be provided in units of pixels, or in a case of a shared pixel structure, the planar transistor Tr is provided in units of a plurality of pixels.

The planar transistor Tr includes a planar gate electrode 41, a gate insulating film 42, and a sidewall 43. FIG. 2 illustrates only a part of the planar transistor Tr located at the pixel boundary portion.

The planar gate electrode 41 includes a lower first gate electrode layer 72A and an upper second gate electrode layer 72B. The upper second gate electrode layer 72B and the lower first gate electrode layer 72A have the same impurity concentration, and the impurity concentration is the same as that of the upper second gate electrode layer 71B of the vertical gate electrode 31.

The vertical gate electrode 31 of the transfer transistor TG and the planar gate electrode 41 of the planar transistor Tr are constituted by polysilicon doped with a P-type impurity such as phosphorus (P). The gate insulating film 32 of the transfer transistor TG and the gate insulating film 42 of the planar transistor Tr are constituted by, for example, a silicon oxide film. The sidewall 33 of the transfer transistor TG and the sidewall 43 of the planar transistor Tr are constituted by an oxide film, a nitride film, or a laminated film thereof.

### <3. Method of Manufacturing Vertical Gate Electrode>

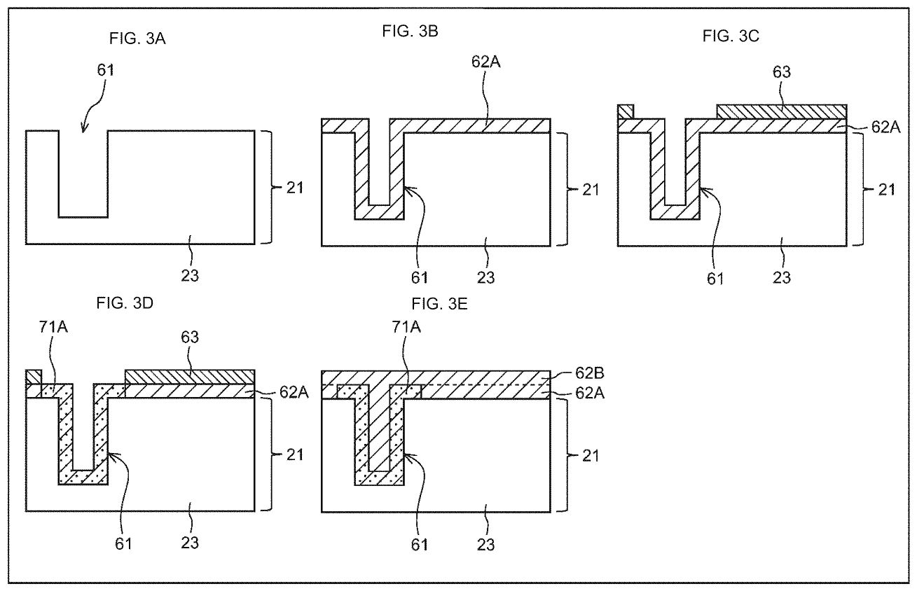

Next, a method of manufacturing the vertical gate electrode 31 of the transfer transistor TG will be described with reference to FIGS. 3 to 5.

First, as illustrated in A of FIG. 3, trenches 61 are formed at a predetermined depth in a predetermined region where the vertical gate electrode 31 of the semiconductor substrate 21 is to be formed, using anisotropic etching or the like.

Next, as illustrated in B of FIG. 3, a polysilicon layer 62A to be a first layer is formed on the side wall and the bottom surface of the trench 61 and the upper surface of the semiconductor substrate 21 by, for example, the LPCVD method or the like. At this time, the film thickness of the polysilicon layer 62A is adjusted to a film thickness that does not block the inside of the trench 61.

Next, as illustrated in C of FIG. 3, a resist 63 is formed on the upper surface of the polysilicon layer 62A on the semiconductor substrate 21, and is patterned so as to open a region where the vertical gate electrode 31 is to be formed.

Next, as illustrated in D of FIG. 3, first ion implantation is performed using the patterned resist 63 as a mask. That is, an N-type impurity such as phosphorus is introduced into the first polysilicon layer 62A. By introducing the N-type impurity at an acceleration voltage adjusted to the film thickness of the polysilicon layer 62A, the inside of the polysilicon layer 62A is made conductive while the penetration of the N-type impurity into the P-well 23 is prevented. A region in which an N-type impurity is introduced into the first polysilicon layer 62A corresponds to the first gate electrode layer 71A.

Next, as illustrated in E of FIG. 3, after the resist 63 is removed, a second polysilicon layer 62B is formed on the first polysilicon layer 62A by, for example, an LPCVD method or the like. As a result, the inside of the trench 61 is closed, and the total film thickness of the first polysilicon layer 62A and the second polysilicon layer 62B formed on the upper surface of the semiconductor substrate 21 becomes the film thickness of the planar portion of the vertical gate electrode 31.

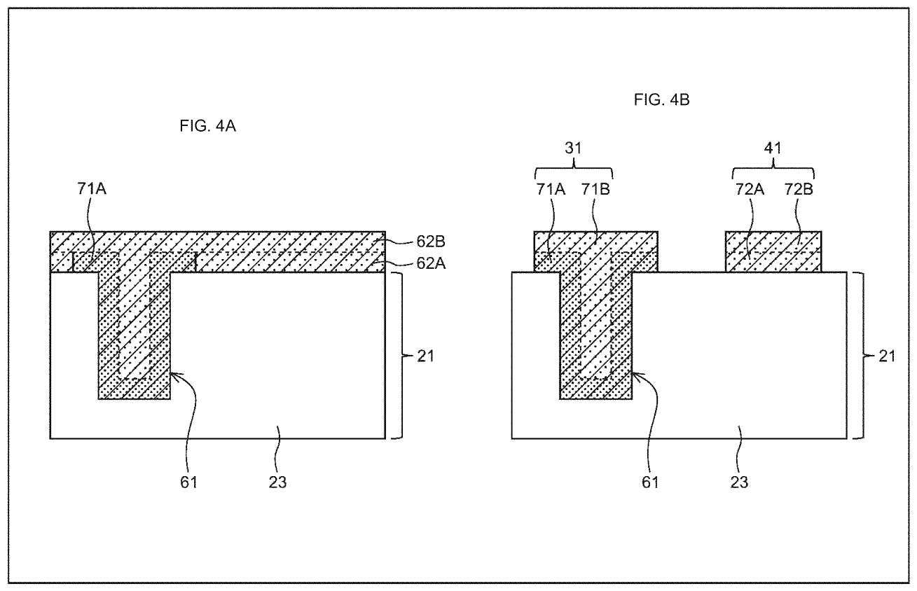

Thereafter, in a case where the same N-type planar MOS transistor as the vertical gate electrode 31 is formed on the same plane as the transfer transistor TG and the planar transistor Tr in FIG. 2, as illustrated in A of FIG. 4, second ion implantation is performed in which an N-type impurity such as phosphorus is introduced without applying a resist to the entire surface where the first polysilicon layer 62A and the second polysilicon layer 62B are formed. Thereafter, as illustrated in B of FIG. 4, by removing the other polysilicon layers 62A and 62B while leaving only the regions of the vertical gate electrode 31 and the planar gate electrode 41 of the planar transistor Tr, the vertical gate electrode 31 of the transfer transistor TG and the planar gate electrode 41 of the planar transistor Tr are simultaneously formed.

The second gate electrode layer 71B of the vertical gate electrode 31 corresponds to a region in which an N-type impurity is introduced into the second polysilicon layer 62B. Since only the second ion implantation is performed in the upper second gate electrode layer 71B, and the first and second ion implantation are performed in the lower first gate electrode layer 71A, a concentration difference occurs in the impurity concentration between the first gate electrode layer 71A and the second gate electrode layer 71B, and the impurity concentration of the first gate electrode layer 71A is higher (darker) than the impurity concentration of the second gate electrode layer 71B.

In the planar gate electrode 41 of the planar transistor Tr, a region corresponding to the first polysilicon layer 62A is the lower first gate electrode layer 72A, and a region corresponding to the second polysilicon layer 62B is the upper second gate electrode layer 72B. Since only the second ion implantation is performed on the lower first gate electrode layer 72A and the upper second gate electrode layer 72B of the planar gate electrode 41, there is no concentration difference between the lower first gate electrode layer 72A and the upper second gate electrode layer 72B.

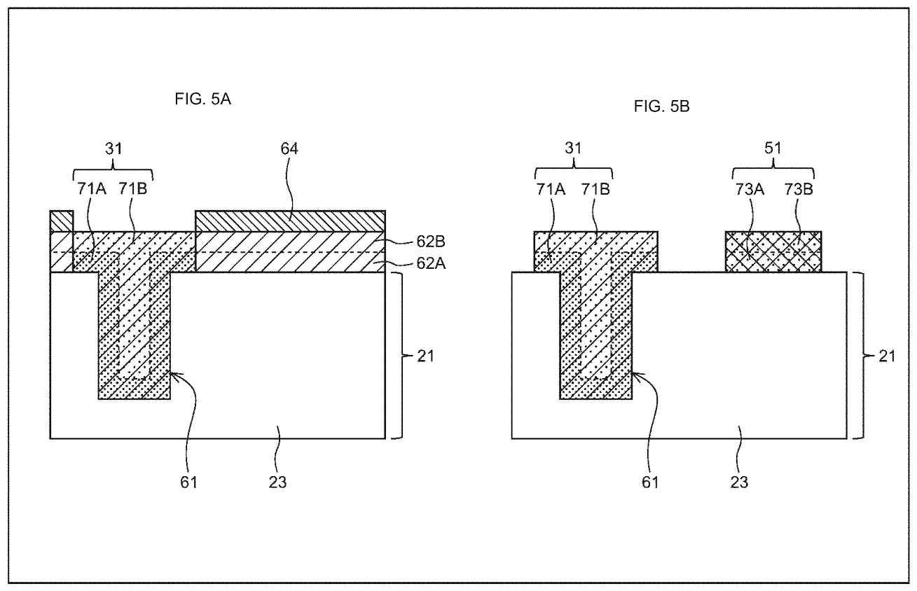

FIG. 5 illustrates a manufacturing method subsequent to E of FIG. 3 in a case where a P-type planar MOS transistor having a conductivity type different from that of the vertical gate electrode 31 is formed on the same plane as the vertical gate electrode 31.

In a case where a P-type planar MOS transistor having a conductivity type different from that of the vertical gate electrode 31 is formed on the same plane as the vertical gate electrode 31, as illustrated in A of FIG. 5, the upper surface of the polysilicon layer 62B other than the region where the vertical gate electrode 31 is formed is covered with a resist 64, and then ion implantation of N-type impurities is performed for the second time. Thus, the lower first gate electrode layer 71A and the upper second gate electrode layer 71B are formed. The point that the impurity concentration of the lower first gate electrode layer 71A is higher than that of the upper second gate electrode layer 71B is similar to FIG. 4.

After the second ion implantation, the resist 64 is removed, and as illustrated in B of FIG. 5, a P-type impurity such as boron is ion-implanted into a region to be the gate electrode 51 of the P-type MOS transistor in the polysilicon layers 62A and 62B into which the N-type impurity is not introduced, whereby the gate electrode 51 of the P-type MOS transistor can be formed. The gate electrode 51 includes a lower first gate electrode layer 73A and an upper second gate electrode layer 73B. The polysilicon layers 62A and 62B other than the vertical gate electrode 31 and the gate electrode 51 are removed.

Whether or not the vertical gate electrode 31 includes two layers of the lower first gate electrode layer 71A and the upper second gate electrode layer 71B can be confirmed with a transmission electron microscope (TEM). In addition, the conductivity type of the impurity introduced into the vertical gate electrode 31, that is, the N type or the P type can be confirmed by a scanning capacitance microscope (SCM). The impurity concentration can also be confirmed by a scanning capacitance microscope, a scanning microwave microscope (SMM), or the like. Therefore, it is possible to verify whether or not the vertical gate electrode structure is the structure of the vertical gate electrode 31 by analyzing the vertical gate electrode structure using a transmission electron microscope, a scanning capacitance microscope, or a scanning microwave microscope.

According to the method of manufacturing the vertical gate electrode 31 described above, the first ion implantation is performed on the first polysilicon layer 62A, and the second ion implantation is performed after the second polysilicon layer 62B is formed. By setting the film thickness of the first polysilicon layer 62A to a film thickness that does not block the inside of the trench 61, the entire first polysilicon layer 62A can be doped with an N-type impurity, and the first gate electrode layer 71A to be a lower layer in the vertical gate electrode 31 in the final state can be easily made conductive.

In addition, in the first ion implantation, the resist 63 is formed in a region other than the region to be the vertical gate electrode 31, so that the impurity to be doped in the region other than the vertical gate electrode 31 can be optimized. That is, a planar N-type MOS transistor can be made in a region other than the vertical gate electrode 31, and a planar P-type MOS transistor can be made.

Furthermore, by forming the vertical gate electrode 31 in two steps of the first polysilicon layer 62A and the second polysilicon layer 62B, there is an advantage that expansion of grains in the polysilicon layer can be suppressed. By suppressing the grain expansion, penetration (leakage) of impurities can be suppressed.

### <4. Effect of Vertical Gate Electrode of Present Disclosure>

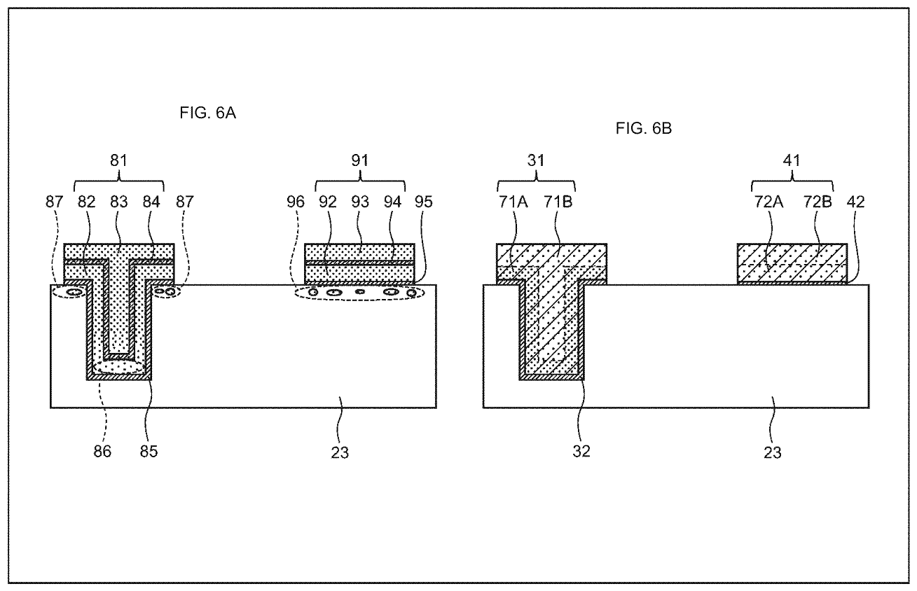

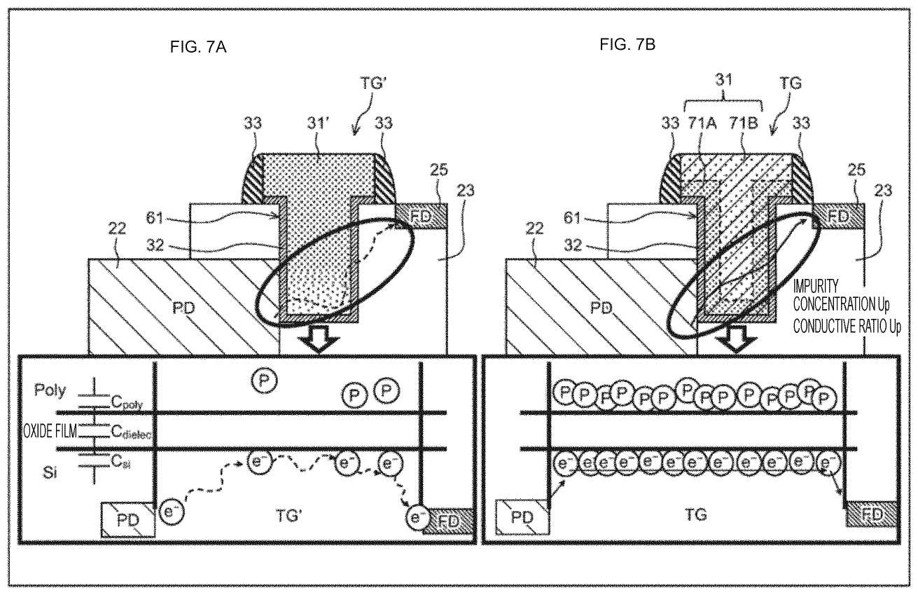

With reference to FIGS. 6 and 7, effects of the vertical gate electrode 31 by comparison with other vertical gate electrode structures will be described.

A of FIG. 6 illustrates an example of a vertical gate electrode and a planar gate electrode disclosed in Patent Document 1 described in the background art.

The vertical gate electrode 81 includes a lower electrode layer 82, an upper electrode layer 83, and a separation layer 84 sandwiched between the lower electrode layer 82 and the upper electrode layer 83. The vertical gate electrode 81 is formed by laminating three layers of the lower electrode layer 82, the upper electrode layer 83, and the separation layer 84, and then ion-implanting N-type impurities. Since the vertical gate electrode 81 is provided with the separation layer 84, impurities ion-implanted into the vertical gate electrode 81 are less likely to penetrate through the vertical gate electrode 81.

On the other hand, in the vertical gate electrode 81, since the N-type impurity is ion-implanted after three layers of the lower electrode layer 82, the upper electrode layer 83, and the separation layer 84 are laminated, the impurity concentration varies between the lower electrode layer 82 and the upper electrode layer 83. Specifically, the impurity concentration is high in the planar portion on the substrate, and the impurity concentration is low at the bottom portion of the embedded portion in the substrate. As a result, for example, non-conductivity may occur in the vicinity of the region 86 at the bottom portion of the embedded portion of the vertical gate electrode 81, or penetration (leakage) of impurities may occur in the vicinity of the substrate region 87 below the planar portion. In other words, it is difficult to achieve both an embedded portion having a large implantation depth of ions and a planar portion having a small implantation depth.

Similarly to the vertical gate electrode 81, the planar gate electrode 91 also includes a lower electrode layer 92, an upper electrode layer 93, and a separation layer 94 sandwiched between the lower electrode layer 92 and the upper electrode layer 93, and is formed by ion implantation of N-type impurities. Also in the planar gate electrode 91, penetration (leakage) of impurities may occur in the vicinity of the substrate region 96 below the planar portion.

In a case where the threshold voltage is different between the MOS transistor of the vertical gate electrode 81 and the MOS transistor of the planar gate electrode 91, and the gate insulating film 95 of the planar gate electrode 91 is formed thinner than the gate insulating film 85 of the vertical gate electrode 81, penetration of impurities under the planar gate electrode 91 is more likely to occur.

On the other hand, in the vertical gate electrode 31 of the transfer transistor TG illustrated in B of FIG. 6, the lower first gate electrode layer 71A and the upper second gate electrode layer 71B are laminated in contact with each other without sandwiching the intermediate layer like the separation layer 84 of the vertical gate electrode 81 in A of FIG. 6. As described above, the first ion implantation of the N-type impurity is performed at the step of forming the first polysilicon layer 62A, and the second ion implantation of the N-type impurity is performed after forming the second polysilicon layer 62B. Since the ion implantation is performed twice, when the N-type impurity is doped into the first polysilicon layer 62A formed with a desired film thickness, the dose amount can be controlled, and the impurity can be reliably doped while penetrating therethrough is prevented. The impurity concentration of the first gate electrode layer 71A as a lower layer in the vertical gate electrode 31 in the final state can be adjusted to a desired concentration. In addition, the second dose amount can be adjusted in accordance with the first gate electrode layer 72A and the second gate electrode layer 72B of the planar transistor Tr. Since the lower first gate electrode layer 71A is laminated on the upper second gate electrode layer 71B without interposing the intermediate layer, the impurity concentration of the lower first gate electrode layer 71A is higher than that of the upper second gate electrode layer 71B.

Therefore, according to the structures of the vertical gate electrode 31 of the transfer transistor TG and the planar gate electrode 41 of the planar transistor Tr and the manufacturing method thereof, it is possible to prevent the trench bottom portion from being nonconductive and the impurities from penetrating (leakage) into the substrate, and to optimize the impurity concentration for each of the vertical gate electrode 31 and the planar gate electrode 41. This makes it possible to achieve both an operation margin and quality of the device.

In addition, in a case where the P-type MOS transistor is formed on the same plane as the transfer transistor TG, since the P-type MOS transistor can be formed by the method described in FIG. 5, it is possible to separately form the N-type MOS transistor and the P-type MOS transistor, and it is possible to increase the degree of freedom in circuit design.

An advantage that the impurity concentration of the lower first gate electrode layer 71A is higher than that of the upper second gate electrode layer 71B in the vertical gate electrode 31 will be described with reference to FIG. 7.

A of FIG. 7 illustrates the transfer transistor TG′ as a comparative example, and B of FIG. 7 illustrates the transfer transistor TG of FIG. 2. In the transfer transistor TG′ of the comparative example, the configuration other than the vertical gate electrode 31′ is similar to that of the transfer transistor TG.

The vertical gate electrode 31′ in A of FIG. 7 is formed by one ion implantation as described in A of FIG. 6, and the impurity concentration is low at the bottom portion of the trench 61.

In the case of the vertical gate electrode 31′ having a low impurity concentration at the bottom portion of the trench 61, the gate capacitance C_{poly} of the vertical gate electrode 31′ becomes low, so that the transfer characteristics of signal charges (electrons) deteriorate.

On the other hand, in the vertical gate electrode 31 of the transfer transistor TG, the impurity concentration of the lower first gate electrode layer 71A can be formed to be higher than that of the vertical gate electrode 31′, and the conductive ratio can be increased. As a result, the gate capacitance C_{poly} of the vertical gate electrode 31 can be increased, and the delay time of the MOS transistor can be reduced. That is, as the transfer transistor TG, transfer characteristics of signal charges (electrons) can be improved, and transistor characteristics can be improved.

### <5. Configuration Example of Electronic Device>

The light detection apparatus 1 described above can be applied to various electronic devices such as an imaging system such as, for example, a digital still camera or a digital video camera, a mobile phone having an imaging function, or another device having an imaging function.

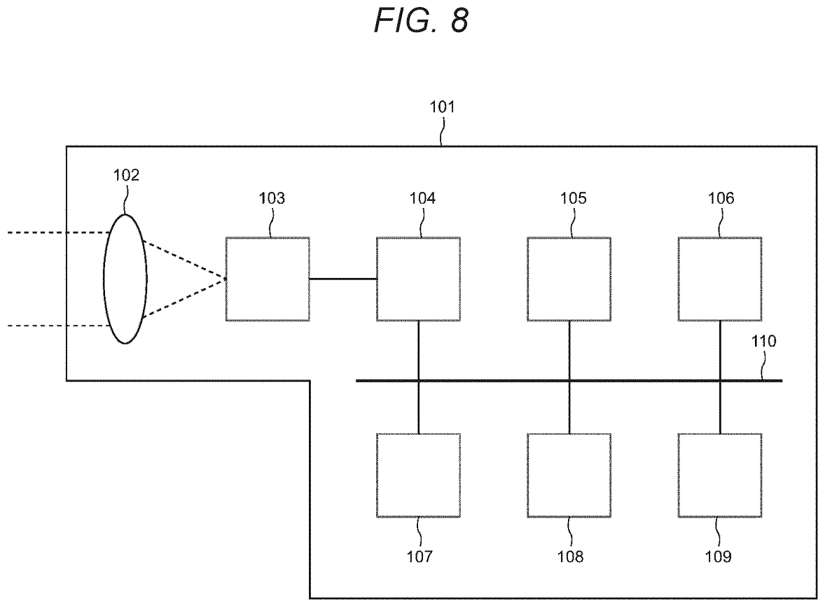

FIG. 8 is a block diagram illustrating an example of a configuration of an electronic device.

As illustrated in FIG. 8, an electronic device 101 includes an optical system 102, a light detection apparatus 103, a digital signal processor (DSP) 104, a display apparatus 105, an operation system 106, a memory 107, a recording apparatus 108, and a power supply system 109. The DSP 104, the display apparatus 105, the operation system 106, the memory 107, the recording apparatus 108, and the power supply system 109 are connected to one another via a bus 110. The electronic device 101 is, for example, an imaging apparatus capable of capturing a still image and a moving image.

The optical system 102 includes one or a plurality of lenses, guides image light (incident light) from a subject to the light detection apparatus 103, and forms an image on a light receiving surface (sensor section) of the light detection apparatus 103.

As the light detection apparatus 103, the configuration of the light detection apparatus 1 described above is applied. In the light detection apparatus 103, electrons as signal charges are accumulated for a certain period according to an image formed on the light receiving surface via the optical system 102. Then, a signal corresponding to the electrons accumulated in the light detection apparatus 103 is supplied to the DSP 104.

The DSP 104 performs various types of signal processing on the signal from the light detection apparatus 103 to generate an image, and temporarily stores data of the image in the memory 107. The image data stored in the memory 107 is recorded in the recording apparatus 108 or supplied to the display apparatus 105 to display an image. In addition, the operation system 106 receives various operations by the user and supplies an operation signal to each block of the electronic device 101, and the power supply system 109 supplies power necessary for driving each block of the electronic device 101.

In the electronic device 101 configured as described above, by applying the above-described light detection apparatus 1 as the light detection apparatus 103, the transfer characteristics of the transfer transistor TG can be improved, and a captured image with high image quality can be generated.

### <6. Use Example of Image Sensor>

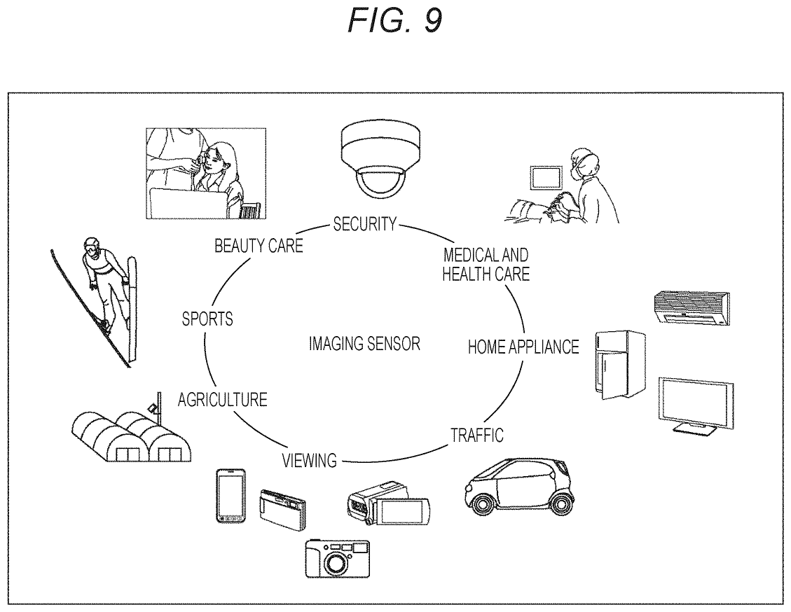

FIG. 9 is a diagram illustrating a use example in a case where the light detection apparatus 1 described above is an image sensor.

In a case where the above-described light detection apparatus 1 is an image sensor, for example, the light detection apparatus 1 can be used in various cases of sensing light such as visible light, infrared light, ultraviolet light, and X-rays as follows.
An apparatus that captures an image to be used for viewing, such as a digital camera and a portable device with a camera function.
An apparatus for traffic purpose such as an in-vehicle sensor which takes images of the front, rear, surroundings, interior and the like of an automobile, a surveillance camera for monitoring traveling vehicles and roads, and a ranging sensor which measures a distance between vehicles and the like for safe driving such as automatic stop, recognition of a driver's condition and the like.
An apparatus for home appliance such as a television, a refrigerator, and an air conditioner that images a user's gesture and performs device operation according to the gesture
An apparatus for medical and health care use such as an endoscope and an apparatus that performs angiography by receiving infrared light
An apparatus for security use such as a surveillance camera and an individual authentication camera
An apparatus used for beauty care, such as a skin condition measuring instrument for imaging skin, and a microscope for imaging the scalp
An apparatus used for sport, such as an action camera or a wearable camera for sports applications or the like
An apparatus used for agriculture, such as a camera for monitoring a condition of a field or crop.

### <7. Application Example to Endoscopic Surgery System>

The technology according to the present disclosure (present technology) can be applied to various products. For example, the technology according to the present disclosure may be applied to an endoscopic surgery system.

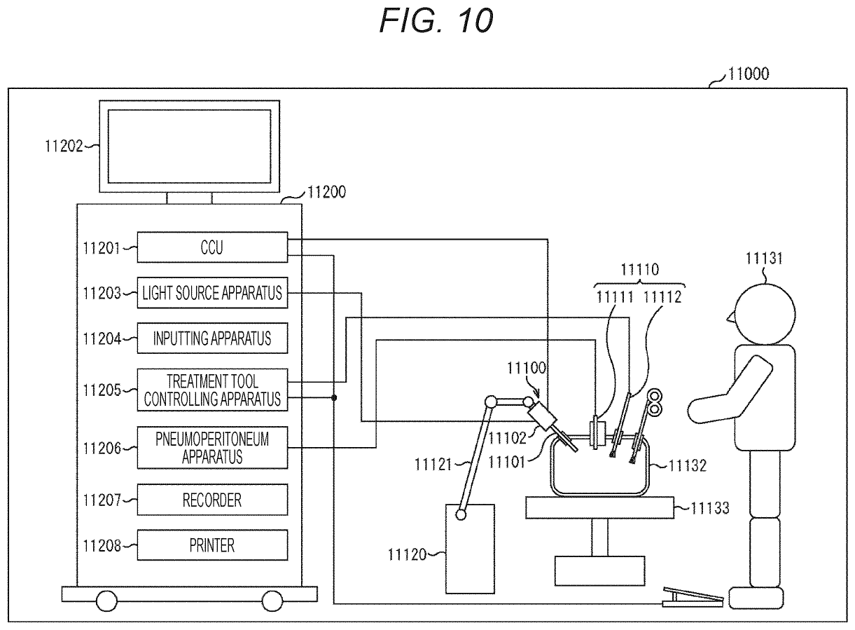

FIG. 10 is a view depicting an example of a schematic configuration of an endoscopic surgery system to which the technology according to an embodiment of the present disclosure (present technology) can be applied.

In FIG. 10, a state is illustrated in which a surgeon (medical doctor) 11131 is using an endoscopic surgery system 11000 to perform surgery for a patient 11132 on a patient bed 11133. As depicted, the endoscopic surgery system 11000 includes an endoscope 11100, other surgical tools 11110 such as a pneumoperitoneum tube 11111 and an energy device 11112, a supporting arm apparatus 11120 which supports the endoscope 11100 thereon, and a cart 11200 on which various apparatus for endoscopic surgery are mounted.

The endoscope 11100 includes a lens barrel 11101 having a region of a predetermined length from a distal end thereof to be inserted into a body cavity of the patient 11132, and a camera head 11102 connected to a proximal end of the lens barrel 11101. In the example depicted, the endoscope 11100 is depicted which includes as a rigid endoscope having the lens barrel 11101 of the hard type. However, the endoscope 11100 may otherwise be included as a flexible endoscope having the lens barrel 11101 of the flexible type.

The lens barrel 11101 has, at a distal end thereof, an opening in which an objective lens is fitted. A light source apparatus 11203 is connected to the endoscope 11100 such that light generated by the light source apparatus 11203 is introduced to a distal end of the lens barrel 11101 by a light guide extending in the inside of the lens barrel 11101 and is irradiated toward an observation target in a body cavity of the patient 11132 through the objective lens. It is to be noted that the endoscope 11100 may be a forward-viewing endoscope or may be an oblique-viewing endoscope or a side-viewing endoscope.

An optical system and an image pickup element are provided in the inside of the camera head 11102 such that reflected light (observation light) from the observation target is condensed on the image pickup element by the optical system. The observation light is photoelectrically converted by the image pickup element to generate an electric signal corresponding to the observation light, namely, an image signal corresponding to an observation image. The image signal is transmitted as RAW data to a CCU 11201.

The CCU 11201 includes a central processing unit (CPU), a graphics processing unit (GPU) or the like and integrally controls operation of the endoscope 11100 and a display apparatus 11202. Further, the CCU 11201 receives an image signal from the camera head 11102 and performs, for the image signal, various image processes for displaying an image based on the image signal such as, for example, a development process (demosaic process).

The display apparatus 11202 displays thereon an image based on an image signal, for which the image processes have been performed by the CCU 11201, under the control of the CCU 11201.

The light source apparatus 11203 includes a light source such as a light emitting diode (LED), for example, and supplies irradiation light for imaging a surgical region to the endoscope 11100.

An inputting apparatus 11204 is an input interface for the endoscopic surgery system 11000. A user can perform inputting of various kinds of information or instruction inputting to the endoscopic surgery system 11000 through the inputting apparatus 11204. For example, the user would input an instruction or a like to change an image pickup condition (type of irradiation light, magnification, focal distance or the like) by the endoscope 11100.

A treatment tool controlling apparatus 11205 controls driving of the energy device 11112 for cautery or incision of a tissue, sealing of a blood vessel or the like. A pneumoperitoneum apparatus 11206 feeds gas into a body cavity of the patient 11132 through the pneumoperitoneum tube 11111 to inflate the body cavity in order to secure the field of view of the endoscope 11100 and secure the working space for the surgeon. A recorder 11207 is an apparatus capable of recording various kinds of information relating to surgery. A printer 11208 is an apparatus capable of printing various kinds of information relating to surgery in various forms such as a text, an image or a graph.

It is to be noted that the light source apparatus 11203 which supplies irradiation light when a surgical region is to be imaged to the endoscope 11100 may include a white light source which includes, for example, an LED, a laser light source or a combination of them. Where a white light source includes a combination of red, green, and blue (RGB) laser light sources, since the output intensity and the output timing can be controlled with a high degree of accuracy for each color (each wavelength), adjustment of the white balance of a picked up image can be performed by the light source apparatus 11203.

Further, in this case, if laser beams from the respective RGB laser light sources are irradiated time-divisionally on an observation target and driving of the image pickup elements of the camera head 11102 are controlled in synchronism with the irradiation timings. Then images individually corresponding to the R, G and B colors can be also picked up time-divisionally. According to this method, a color image can be obtained even if color filters are not provided for the image pickup element.

Further, the light source apparatus 11203 may be controlled such that the intensity of light to be outputted is changed for each predetermined time. By controlling driving of the image pickup element of the camera head 11102 in synchronism with the timing of the change of the intensity of light to acquire images time-divisionally and synthesizing the images, an image of a high dynamic range free from underexposed blocked up shadows and overexposed highlights can be created.

Further, the light source apparatus 11203 may be configured to supply light of a predetermined wavelength band ready for special light observation. In special light observation, for example, by utilizing the wavelength dependency of absorption of light in a body tissue to irradiate light of a narrow band in comparison with irradiation light upon ordinary observation (namely, white light), narrow band observation (narrow band imaging) of imaging a predetermined tissue such as a blood vessel of a superficial portion of the mucous membrane or the like in a high contrast is performed. Alternatively, in special light observation, fluorescent observation for obtaining an image from fluorescent light generated by irradiation of excitation light may be performed. In fluorescent observation, it is possible to perform observation of fluorescent light from a body tissue by irradiating excitation light on the body tissue (autofluorescence observation) or to obtain a fluorescent light image by locally injecting a reagent such as indocyanine green (ICG) into a body tissue and irradiating excitation light corresponding to a fluorescent light wavelength of the reagent upon the body tissue. The light source apparatus 11203 can be configured to supply such narrow-band light and/or excitation light suitable for special light observation as described above.

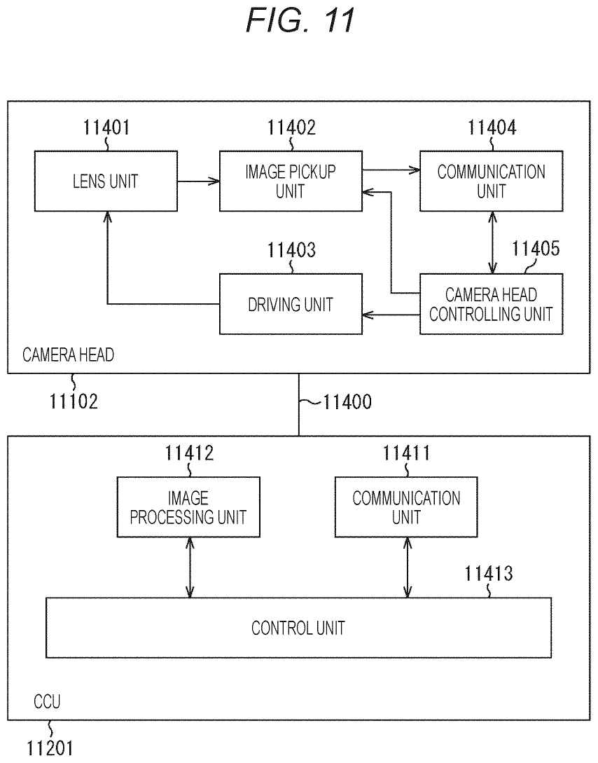

FIG. 11 is a block diagram depicting an example of a functional configuration of the camera head 11102 and the CCU 11201 depicted in FIG. 10.

The camera head 11102 includes a lens unit 11401, an image pickup unit 11402, a driving unit 11403, a communication unit 11404 and a camera head controlling unit 11405. The CCU 11201 includes a communication unit 11411, an image processing unit 11412 and a control unit 11413. The camera head 11102 and the CCU 11201 are connected for communication to each other by a transmission cable 11400.

The lens unit 11401 is an optical system, provided at a connecting location to the lens barrel 11101. Observation light taken in from a distal end of the lens barrel 11101 is guided to the camera head 11102 and introduced into the lens unit 11401. The lens unit 11401 includes a combination of a plurality of lenses including a zoom lens and a focusing lens.

The image pickup unit 11402 includes an image pickup element. The number of image pickup elements which is included by the image pickup unit 11402 may be one (single-plate type) or a plural number (multi-plate type). Where the image pickup unit 11402 is configured as that of the multi-plate type, for example, image signals corresponding to respective R, G and B are generated by the image pickup elements, and the image signals may be synthesized to obtain a color image. Alternatively, the image pickup unit 11402 may include a pair of image pickup elements for acquiring right-eye and left-eye image signals corresponding to three-dimensional (3D) display. If 3D display is performed, then the depth of a living body tissue in a surgical region can be comprehended more accurately by the surgeon 11131. It is to be noted that, where the image pickup unit 11402 is configured as that of stereoscopic type, a plurality of systems of lens units 11401 are provided corresponding to the individual image pickup elements.

Further, the image pickup unit 11402 may not necessarily be provided on the camera head 11102. For example, the image pickup unit 11402 may be provided immediately behind the objective lens in the inside of the lens barrel 11101.

The driving unit 11403 includes an actuator and moves the zoom lens and the focusing lens of the lens unit 11401 by a predetermined distance along an optical axis under the control of the camera head controlling unit 11405. Consequently, the magnification and the focal point of a picked up image by the image pickup unit 11402 can be adjusted suitably.

The communication unit 11404 includes a communication apparatus for transmitting and receiving various kinds of information to and from the CCU 11201. The communication unit 11404 transmits an image signal acquired from the image pickup unit 11402 as RAW data to the CCU 11201 through the transmission cable 11400.

In addition, the communication unit 11404 receives a control signal for controlling driving of the camera head 11102 from the CCU 11201 and supplies the control signal to the camera head controlling unit 11405. The control signal includes information relating to image pickup conditions such as, for example, information that a frame rate of a picked up image is designated, information that an exposure value upon image picking up is designated and/or information that a magnification and a focal point of a picked up image are designated.

It is to be noted that the image pickup conditions such as the frame rate, exposure value, magnification or focal point may be designated by the user or may be set automatically by the control unit 11413 of the CCU 11201 on the basis of an acquired image signal. In the latter case, an auto exposure (AE) function, an auto focus (AF) function and an auto white balance (AWB) function are incorporated in the endoscope 11100.

The camera head controlling unit 11405 controls driving of the camera head 11102 on the basis of a control signal from the CCU 11201 received through the communication unit 11404.

The communication unit 11411 includes a communication apparatus for transmitting and receiving various kinds of information to and from the camera head 11102. The communication unit 11411 receives an image signal transmitted thereto from the camera head 11102 through the transmission cable 11400.

Further, the communication unit 11411 transmits a control signal for controlling driving of the camera head 11102 to the camera head 11102. The image signal and the control signal can be transmitted by electrical communication, optical communication or the like.

The image processing unit 11412 performs various image processes for an image signal in the form of RAW data transmitted thereto from the camera head 11102.

The control unit 11413 performs various kinds of control relating to image picking up of a surgical region or the like by the endoscope 11100 and display of a picked up image obtained by image picking up of the surgical region or the like. For example, the control unit 11413 creates a control signal for controlling driving of the camera head 11102.

Further, the control unit 11413 controls, on the basis of an image signal for which image processes have been performed by the image processing unit 11412, the display apparatus 11202 to display a picked up image in which the surgical region or the like is imaged. Thereupon, the control unit 11413 may recognize various objects in the picked up image using various image recognition technologies. For example, the control unit 11413 can recognize a surgical tool such as forceps, a particular living body region, bleeding, mist when the energy device 11112 is used and so forth by detecting the shape, color and so forth of edges of objects included in a picked up image. The control unit 11413 may cause, when it controls the display apparatus 11202 to display a picked up image, various kinds of surgery supporting information to be displayed in an overlapping manner with an image of the surgical region using a result of the recognition. Where surgery supporting information is displayed in an overlapping manner and presented to the surgeon 11131, the burden on the surgeon 11131 can be reduced and the surgeon 11131 can proceed with the surgery with certainty.

The transmission cable 11400 which connects the camera head 11102 and the CCU 11201 to each other is an electric signal cable ready for communication of an electric signal, an optical fiber ready for optical communication or a composite cable ready for both of electrical and optical communications.

Here, while, in the example depicted, communication is performed by wired communication using the transmission cable 11400, the communication between the camera head 11102 and the CCU 11201 may be performed by wireless communication.

An example of the endoscopic surgery system to which the technology according to the present disclosure can be applied has been described above. The technology according to the present disclosure may be applied to the image pickup unit 11402 of the camera head 11102 in the configuration described above. Specifically, the light detection apparatus 1 described above can be applied as the image pickup unit 11402. By applying the technology according to the present disclosure to the image pickup unit 11402 and improving the signal charge transfer characteristics, a clearer surgical region image can be obtained.

Note that an endoscopic surgery system has been described as an example herein, but the technology according to the present disclosure may be applied to a microscopic surgery system or the like, for example.

### <8. Application Example to Mobile Body>

The technology according to the present disclosure (present technology) can be applied to various products. For example, the technology according to the present disclosure may be achieved in the form of an apparatus to be mounted on a mobile body of any kind, such as an automobile, an electric vehicle, a hybrid electric vehicle, a motorcycle, a bicycle, a personal mobility, an airplane, a drone, a vessel, or a robot.

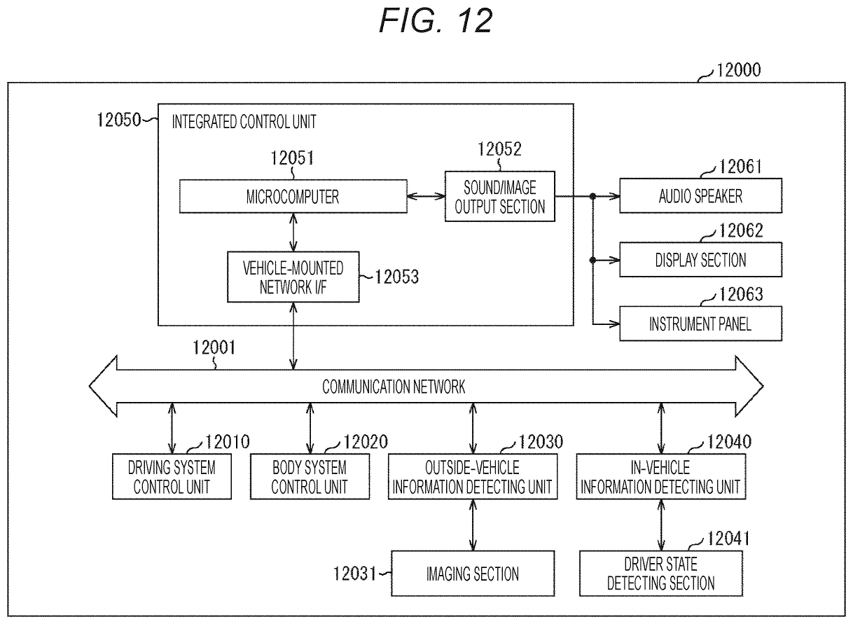

FIG. 12 is a block diagram depicting an example of schematic configuration of a vehicle control system as an example of a mobile body control system to which the technology according to an embodiment of the present disclosure can be applied.

The vehicle control system 12000 includes a plurality of electronic control units connected to each other via a communication network 12001. In the example depicted in FIG. 12, the vehicle control system 12000 includes a driving system control unit 12010, a body system control unit 12020, an outside-vehicle information detecting unit 12030, an in-vehicle information detecting unit 12040, and an integrated control unit 12050. Furthermore, a microcomputer 12051, a sound/image output section 12052, and a vehicle-mounted network interface (I/F) 12053 are illustrated as a functional configuration of the integrated control unit 12050.

The driving system control unit 12010 controls the operation of devices related to the driving system of the vehicle in accordance with various kinds of programs. For example, the driving system control unit 12010 functions as a control device for a driving force generating device for generating the driving force of the vehicle, such as an internal combustion engine, a driving motor, or the like, a driving force transmitting mechanism for transmitting the driving force to wheels, a steering mechanism for adjusting the steering angle of the vehicle, a braking device for generating the braking force of the vehicle, and the like.

The body system control unit 12020 controls the operation of various kinds of devices provided to a vehicle body in accordance with various kinds of programs. For example, the body system control unit 12020 functions as a control device for a keyless entry system, a smart key system, a power window device, or various kinds of lamps such as a headlamp, a backup lamp, a brake lamp, a turn signal, a fog lamp, or the like. In this case, radio waves transmitted from a mobile device as an alternative to a key or signals of various kinds of switches can be input to the body system control unit 12020. The body system control unit 12020 receives these input radio waves or signals, and controls a door lock device, the power window device, the lamps, or the like of the vehicle.

The outside-vehicle information detecting unit 12030 detects information about the outside of the vehicle including the vehicle control system 12000. For example, the outside-vehicle information detecting unit 12030 is connected with an imaging section 12031. The outside-vehicle information detecting unit 12030 makes the imaging section 12031 image an image of the outside of the vehicle, and receives the imaged image. On the basis of the received image, the outside-vehicle information detecting unit 12030 may perform processing of detecting an object such as a human, a vehicle, an obstacle, a sign, a character on a road surface, or the like, or processing of detecting a distance thereto.

The imaging section 12031 is an optical sensor that receives light, and which outputs an electric signal corresponding to a received light amount of the light. The imaging section 12031 can output the electric signal as an image, or can output the electric signal as information about a measured distance. In addition, the light received by the imaging section 12031 may be visible light, or may be invisible light such as infrared rays or the like.

The in-vehicle information detecting unit 12040 detects information about the inside of the vehicle. The in-vehicle information detecting unit 12040 is, for example, connected with a driver state detecting section 12041 that detects the state of a driver. The driver state detecting section 12041, for example, includes a camera that images the driver. On the basis of detection information input from the driver state detecting section 12041, the in-vehicle information detecting unit 12040 may calculate a degree of fatigue of the driver or a degree of concentration of the driver, or may determine whether the driver is dozing.

The microcomputer 12051 can calculate a control target value for the driving force generating device, the steering mechanism, or the braking device on the basis of the information about the inside or outside of the vehicle which information is obtained by the outside-vehicle information detecting unit 12030 or the in-vehicle information detecting unit 12040, and output a control command to the driving system control unit 12010. For example, the microcomputer 12051 can perform cooperative control intended to implement functions of an advanced driver assistance system (ADAS) which functions include collision avoidance or shock mitigation for the vehicle, following driving based on a following distance, vehicle speed maintaining driving, a warning of collision of the vehicle, a warning of deviation of the vehicle from a lane, or the like.

In addition, the microcomputer 12051 can perform cooperative control intended for automated driving, which makes the vehicle to travel automatedly without depending on the operation of the driver, or the like, by controlling the driving force generating device, the steering mechanism, the braking device, or the like on the basis of the information about the outside or inside of the vehicle which information is obtained by the outside-vehicle information detecting unit 12030 or the in-vehicle information detecting unit 12040.

In addition, the microcomputer 12051 can output a control command to the body system control unit 12020 on the basis of the information about the outside of the vehicle which information is acquired by the outside-vehicle information detecting unit 12030. For example, the microcomputer 12051 can perform cooperative control intended to prevent a glare by controlling the headlamp so as to change from a high beam to a low beam, for example, in accordance with the position of a preceding vehicle or an oncoming vehicle detected by the outside-vehicle information detecting unit 12030.

The sound/image output section 12052 transmits an output signal of at least one of a sound and an image to an output device capable of visually or auditorily notifying information to an occupant of the vehicle or the outside of the vehicle. In the example of FIG. 12, an audio speaker 12061, a display section 12062, and an instrument panel 12063 are illustrated as the output device. The display section 12062 may, for example, include at least one of an on-board display and a head-up display.

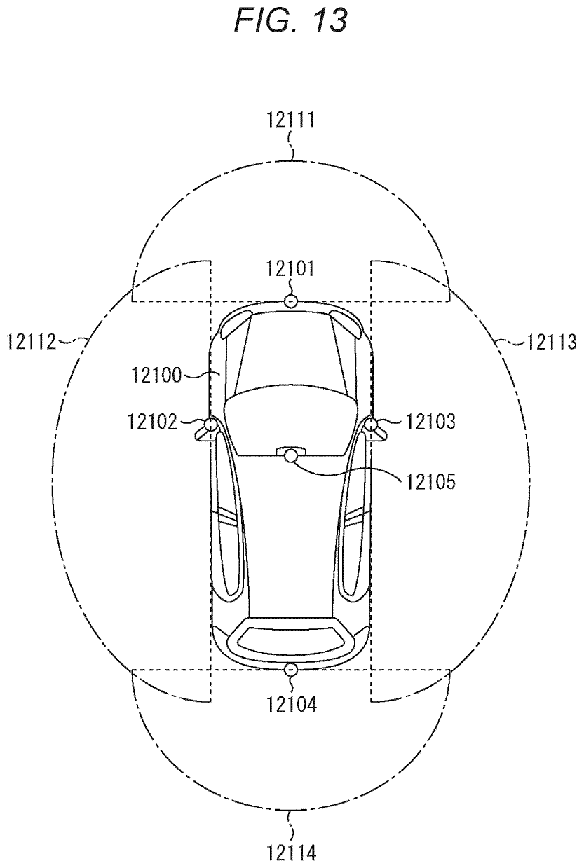

FIG. 13 is a diagram depicting an example of the installation position of the imaging section 12031.

In FIG. 13, a vehicle 12100 includes imaging sections 12101, 12102, 12103, 12104, and 12105, as the imaging section 12031.

The imaging sections 12101, 12102, 12103, 12104, 12105 are provided, for example, at positions such as a front nose, a sideview mirror, a rear bumper, a back door, and an upper portion of a windshield in the interior of a vehicle 12100. The imaging section 12101 provided to the front nose and the imaging section 12105 provided to the upper portion of the windshield within the interior of the vehicle obtain mainly an image of the front of the vehicle 12100. The imaging sections 12102 and 12103 provided to the sideview mirrors acquire mainly an image of the sides of the vehicle 12100. The imaging section 12104 provided to the rear bumper or the back door obtains mainly an image of the rear of the vehicle 12100. The forward images acquired by the imaging sections 12101 and 12105 are used mainly to detect a preceding vehicle, a pedestrian, an obstacle, a traffic signal, a traffic sign, a lane, or the like.

Incidentally, FIG. 13 depicts an example of capturing ranges of the imaging sections 12101 to 12104. An imaging range 12111 represents the imaging range of the imaging section 12101 provided to the front nose. Imaging ranges 12112 and 12113 respectively represent the imaging ranges of the imaging sections 12102 and 12103 provided to the sideview mirrors. An imaging range 12114 represents the imaging range of the imaging section 12104 provided to the rear bumper or the back door. A bird's-eye image of the vehicle 12100 as viewed from above is obtained by superimposing image data imaged by the imaging sections 12101 to 12104, for example.

At least one of the imaging sections 12101 to 12104 may have a function of obtaining distance information. For example, at least one of the imaging sections 12101 to 12104 may be a stereo camera constituted of a plurality of imaging elements, or may be an imaging element having pixels for phase difference detection.

For example, the microcomputer 12051 can determine a distance to each three-dimensional object within the imaging ranges 12111 to 12114 and a temporal change in the distance (relative speed with respect to the vehicle 12100) on the basis of the distance information obtained from the imaging sections 12101 to 12104, and thereby extract, as a preceding vehicle, a nearest three-dimensional object in particular that is present on a traveling path of the vehicle 12100 and which travels in substantially the same direction as the vehicle 12100 at a predetermined speed (for example, equal to or more than 0 km/hour). Further, the microcomputer 12051 can set a following distance to be maintained in front of a preceding vehicle in advance, and perform automatic brake control (including following stop control), automatic acceleration control (including following start control), or the like. It is thus possible to perform cooperative control intended for automated driving that makes the vehicle travel automatedly without depending on the operation of the driver or the like.

For example, the microcomputer 12051 can classify three-dimensional object data on three-dimensional objects into three-dimensional object data of a two-wheeled vehicle, a standard-sized vehicle, a large-sized vehicle, a pedestrian, a utility pole, and other three-dimensional objects on the basis of the distance information obtained from the imaging sections 12101 to 12104, extract the classified three-dimensional object data, and use the extracted three-dimensional object data for automatic avoidance of an obstacle. For example, the microcomputer 12051 identifies obstacles around the vehicle 12100 as obstacles that the driver of the vehicle 12100 can recognize visually and obstacles that are difficult for the driver of the vehicle 12100 to recognize visually. Then, the microcomputer 12051 determines a collision risk indicating a risk of collision with each obstacle. In a situation in which the collision risk is equal to or higher than a set value and there is thus a possibility of collision, the microcomputer 12051 outputs a warning to the driver via the audio speaker 12061 or the display section 12062, and performs forced deceleration or avoidance steering via the driving system control unit 12010. The microcomputer 12051 can thereby assist in driving to avoid collision.

At least one of the imaging sections 12101 to 12104 may be an infrared camera that detects infrared rays. The microcomputer 12051 can, for example, recognize a pedestrian by determining whether or not there is a pedestrian in imaged images of the imaging sections 12101 to 12104. Such recognition of a pedestrian is, for example, performed by a procedure of extracting characteristic points in the imaged images of the imaging sections 12101 to 12104 as infrared cameras and a procedure of determining whether or not it is the pedestrian by performing pattern matching processing on a series of characteristic points representing the contour of the object. When the microcomputer 12051 determines that there is a pedestrian in the imaged images of the imaging sections 12101 to 12104, and thus recognizes the pedestrian, the sound/image output section 12052 controls the display section 12062 so that a square contour line for emphasis is displayed so as to be superimposed on the recognized pedestrian. The sound/image output section 12052 may also control the display section 12062 so that an icon or the like representing the pedestrian is displayed at a desired position.

An example of the vehicle control system to which the technology according to the present disclosure can be applied has been described above. The technology according to the present disclosure can be applied to the imaging section 12031 among the configurations described above. Specifically, the light detection apparatus 1 described above can be applied as the imaging section 12031. By applying the technology according to the present disclosure to the imaging section 12031, a more easily viewable captured image can be obtained, and distance information can be acquired. Furthermore, it is possible to reduce driver's fatigue and increase the safety of the driver and the vehicle by using the obtained captured image and distance information.

In the above-described example, the light detection apparatus using electrons as signal charges has been described, but it goes without saying that the present disclosure can also be applied to a light detection apparatus using holes as signal charges.

Furthermore, the present disclosure is not limited to application to a light detection apparatus that detects a distribution of the amount of incident light of visible light and captures the distribution as an image, and can be applied to all light detection apparatuses (physical quantity distribution detection apparatuses) such as a light detection apparatus that captures a distribution of the amount of incident infrared rays, X-rays, particles, or the like as an image, and a fingerprint detection sensor that detects a distribution of other physical quantities such as pressure and capacitance and captures the distribution as an image in a broad sense.

In addition, the technology of the present disclosure is applicable not only to the light detection apparatus but also to all semiconductor apparatuses having other semiconductor integrated circuits.

The embodiment of the present disclosure is not limited to the above-described embodiment and various modifications may be made without departing from the gist of the technology of the present disclosure.

Note that, the effects described in the present specification are merely examples and are not limited, and there may be effects other than those described in the present specification.

Note that the technology of the present disclosure can have the following configurations.

(1)

A vertical transistor including
a vertical gate electrode including:
a first gate electrode layer formed on a side wall and a bottom portion of a trench and having a first impurity concentration; and
a second gate electrode layer formed on the first gate electrode layer and having a second impurity concentration different from the first impurity concentration.
   (2)

The vertical transistor according to (1),
in which the second impurity concentration is lower than the first impurity concentration.
   (3)

The vertical transistor according to (1) or (2),
in which the second gate electrode layer is also formed inside the first gate electrode layer in the trench.
   (4)

The vertical transistor according to any one of (1) to (3),
in which the first gate electrode layer and the second gate electrode layer are laminated in contact with each other.
   (5)

The vertical transistor according to any one of (1) to (4),
in which the vertical transistor is a transfer transistor that transfers electric charge generated by a photodiode to a floating diffusion.
   (6)

The vertical transistor according to any one of (1) to (5),
in which a planar transistor having a same conductivity type as the vertical transistor is formed on a same plane.
   (7)

The vertical transistor according to any one of (1) to (5),
in which a planar transistor having a conductivity type different from the vertical transistor is formed on a same plane.
   (8)

The vertical transistor according to (7),
in which the planar transistor includes a lower first gate electrode layer and an upper second gate electrode layer, and
impurity concentrations of the first gate electrode layer and the second gate electrode layer of the planar transistor are same as the second gate electrode layer of the vertical gate electrode.
   (9)

A light detection apparatus including
a vertical transistor including a vertical gate electrode including:
a first gate electrode layer formed on a side wall and a bottom portion of a trench and having a first impurity concentration; and
a second gate electrode layer formed on the first gate electrode layer and having a second impurity concentration different from the first impurity concentration.
   (10)

An electronic device including
a light detection apparatus including
a vertical transistor including a vertical gate electrode including:
a first gate electrode layer formed on a side wall and a bottom portion of a trench and having a first impurity concentration; and
a second gate electrode layer formed on the first gate electrode layer and having a second impurity concentration different from the first impurity concentration.

### REFERENCE SIGNS LIST

1 Light detection apparatus
2 Pixel
3 Pixel array section
PD Photodiode
TG Transfer transistor
Tr Planar transistor
21 Semiconductor substrate
22 N-type semiconductor region
23 P-well
24 P-type semiconductor region
25 High-concentration N-type semiconductor region
26 N-type semiconductor region
31 Vertical gate electrode
32 Gate insulating film
33 Sidewall
41 Planar gate electrode
42 Gate insulating film
43 Sidewall
51 Gate electrode
61 Trench
71A First gate electrode layer
71B Second gate electrode layer
72A First gate electrode layer
72B Second gate electrode layer
101 Electronic device
103 Light detection apparatus

1. A vertical transistor including
a vertical gate electrode comprising:
a first gate electrode layer formed on a side wall and a bottom portion of a trench and having a first impurity concentration; and
a second gate electrode layer formed on the first gate electrode layer and having a second impurity concentration different from the first impurity concentration.

2. The vertical transistor according to claim 1,
wherein the second impurity concentration is lower than the first impurity concentration.

3. The vertical transistor according to claim 1,
wherein the second gate electrode layer is also formed inside the first gate electrode layer in the trench.

4. The vertical transistor according to claim 1,
wherein the first gate electrode layer and the second gate electrode layer are laminated in contact with each other.

5. The vertical transistor according to claim 1,
wherein the vertical transistor is a transfer transistor that transfers electric charge generated by a photodiode to a floating diffusion.

6. The vertical transistor according to claim 1,
wherein a planar transistor having a same conductivity type as the vertical transistor is formed on a same plane.

7. The vertical transistor according to claim 1,
wherein a planar transistor having a conductivity type different from the vertical transistor is formed on a same plane.

8. The vertical transistor according to claim 6,
wherein the planar transistor includes a lower first gate electrode layer and an upper second gate electrode layer, and
impurity concentrations of the first gate electrode layer and the second gate electrode layer of the planar transistor are same as the second gate electrode layer of the vertical gate electrode.

9. A light detection apparatus including
a vertical transistor including a vertical gate electrode comprising:
a first gate electrode layer formed on a side wall and a bottom portion of a trench and having a first impurity concentration; and
a second gate electrode layer formed on the first gate electrode layer and having a second impurity concentration different from the first impurity concentration.

10. An electronic device including
a light detection apparatus including
a vertical transistor including a vertical gate electrode comprising:
a first gate electrode layer formed on a side wall and a bottom portion of a trench and having a first impurity concentration; and
a second gate electrode layer formed on the first gate electrode layer and having a second impurity concentration different from the first impurity concentration.
